(19) United States
(12) Patent Application Publication
(10) Pub. No.: US 2018/0095050 A1
(43) Pub. Date: Apr. 5, 2018

(54) NON-ENZYMATIC GLUCOSE BIOSENSOR AND MANUFACTURING METHOD THEREOF AND MANUFACTURING METHOD OF NANOMETAL CATALYST

(71) Applicant: National Tsing Hua University, Hsinchu City (TW)

(72) Inventors: Fan-Gang Tseng, Taipei City (TW); Yu-Hsuan Wei, Taipei City (TW)

(73) Assignee: National Tsing Hua University, Hsinchu City (TW)

(21) Appl. No.: 15/415,645

(22) Filed: Jan. 25, 2017

(30) Foreign Application Priority Data
Oct. 3, 2016 (TW) 105131874

(51) Int. Cl. G01N 27/327; C30B 19/10; C30B 30/02; C30B 29/02

(52) U.S. Cl. CPC G01N 27/3275; C30B 29/02; C30B 30/02; C30B 19/103

(57) ABSTRACT

A non-enzymatic glucose biosensor and a manufacturing method thereof and a manufacturing method of a nanometal catalyst are provided. The non-enzymatic glucose biosensor includes a voltage source and a working electrode. The working electrode is electrically connected to the voltage source, wherein the working electrode includes a substrate and a nanometal catalyst. The nanometal catalyst is deposited on the substrate and includes polygonal block nanostructures, wherein the nanometal catalyst catalyzes the oxidation reaction of glucose.

### CROSS-REFERENCE TO RELATED APPLICATION

This application claims the priority benefit of Taiwan application serial no. 105131874, filed on Oct. 3, 2016. The entirety of the above-mentioned patent application is hereby incorporated by reference herein and made a part of this specification.

### BACKGROUND OF THE INVENTION

### Field of the Invention

The invention relates to a non-enzymatic glucose biosensor and a manufacturing method thereof and a manufacturing method of a nanometal catalyst, and more particularly, to a non-enzymatic glucose biosensor adopting a nanometal catalyst and a manufacturing method thereof and a manufacturing method of the nanometal catalyst.

### Description of Related Art

The electrochemical sensor allows a user to determine the amount of a substance mainly by sensing the reaction of the material on the electrode surface and the substance and outputting a potential or a current signal via a sensor. Since the electrode is depended on as the main detection tool, the selection of the electrode material is very important. In general, based on whether enzyme combination occurs, the electrochemical sensor can be divided into a non-enzymatic electrochemical sensor and an enzyme electrochemical sensor. In particular, due to the more stringent storage conditions of the enzyme, such as a low temperature not greater than 4° C., the development of the enzyme electrochemical sensor is limited.

### SUMMARY OF THE INVENTION

The invention provides a non-enzymatic glucose biosensor, wherein the oxidation reaction of glucose is catalyzed using a nanometal catalyst, and therefore excellent sensitivity and linear interval are achieved.

The invention further provides a manufacturing method of a nanometal catalyst having the advantages of simple process and low equipment requirement.

The invention further provides a manufacturing method of a non-enzymatic glucose biosensor having the advantages of simple process and low equipment requirement and suitable for commercial mass production.

The non-enzymatic glucose biosensor of the invention includes a voltage source and a working electrode. The working electrode is electrically connected to the voltage source and includes a substrate and a nanometal catalyst, wherein the nanometal catalyst is deposited on the substrate and includes polygonal block nanostructures, and the nanometal catalyst catalyzes the oxidation reaction of glucose.

In an embodiment of the invention, the width of the polygonal block nanostructures is between 50 nm and 100 nm.

In an embodiment of the invention, the nanometal catalyst has a face-centered cubic single crystal structure.

In an embodiment of the invention, the material of the nanometal catalyst includes platinum.

In an embodiment of the invention, the nanometal catalyst further includes coniferous nanostructures.

In an embodiment of the invention, the material of the substrate includes a soft flexible material.

In an embodiment of the invention, the non-enzymatic glucose biosensor further includes an opposite electrode and a reference electrode respectively electrically connected to the voltage source.

The invention provides a manufacturing method of a nanometal catalyst, including: providing a conductive material; bringing the conductive material in contact with an electroplating solution, the electroplating solution including: sulfuric acid, chloroplatinic acid, or a combination thereof; and performing micro-electroplating under the condition of a voltage of 0.6 V to −0.5 V.

In an embodiment of the invention, the pH value of the electroplating solution used in the micro-electroplating process is between 1 and 2.

The invention provides a manufacturing method of a non-enzymatic glucose biosensor, including: providing a voltage source; and providing a working electrode electrically connected to the voltage source, wherein the working electrode includes a nanometal catalyst, and the nanometal catalyst is manufactured by the manufacturing method of the nanometal catalyst.

The non-enzymatic glucose biosensor of the invention does not use an enzyme to catalyze the oxidation reaction of glucose, but instead uses a nanometal catalyst to catalyze the oxidation reaction of glucose, and therefore excellent linear interval is achieved. Moreover, the manufacturing method of the nanometal catalyst of the invention has the advantages of simple process and low equipment requirement, and is therefore suitable for the commercial mass production of the non-enzymatic glucose biosensor adopting the manufacturing method.

In order to make the aforementioned features and advantages of the disclosure more comprehensible, embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic diagram of a non-enzymatic biosensor of an embodiment of the invention.

FIG. 2 is a scanning electron microscope (SEM) image of a nanometal catalyst of an embodiment of the invention.

FIG. 3 shows the relationship of current density and glucose concentration of the non-enzymatic biosensor of an embodiment of the invention.

### DESCRIPTION OF THE EMBODIMENTS

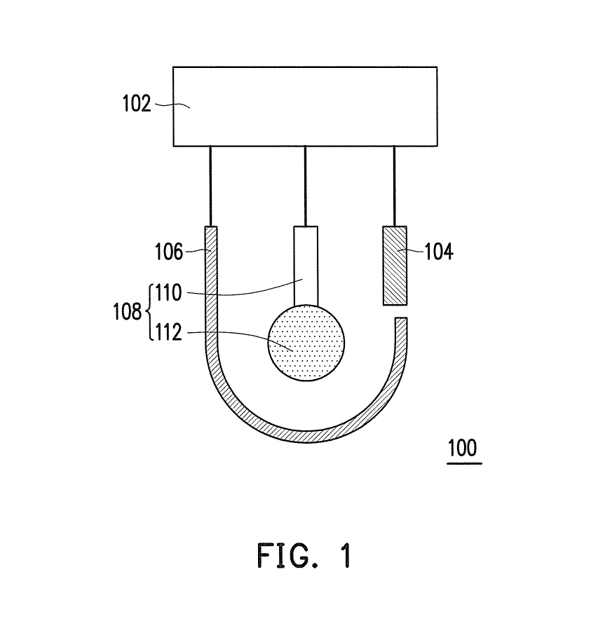

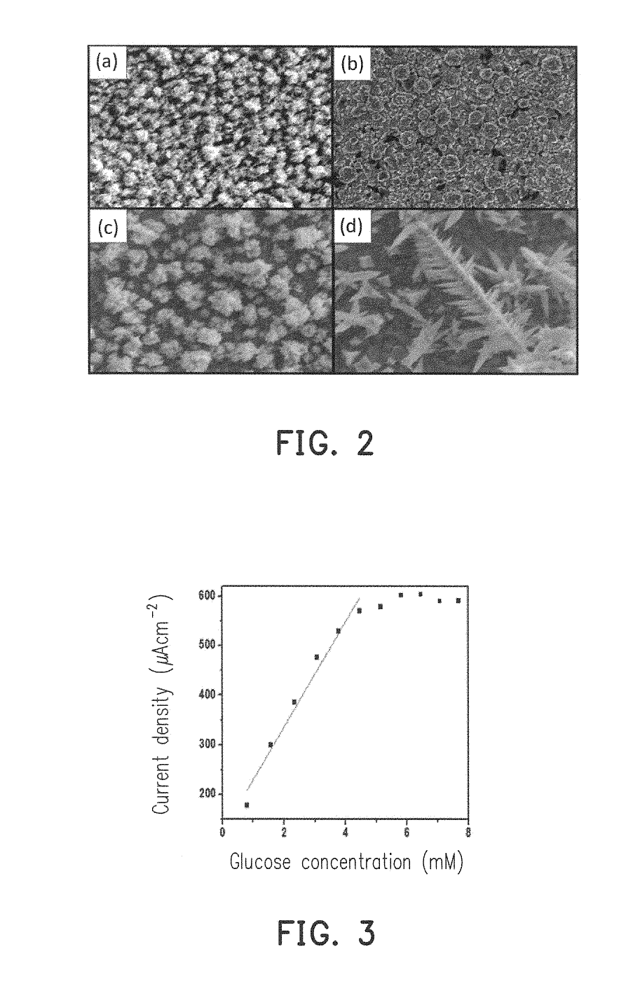

FIG. 1 is a schematic diagram of a non-enzymatic biosensor of an embodiment of the invention. In FIG. 2, (a) to (d) are respectively a SEM image of a nanometal catalyst of an embodiment of the invention. Referring to FIG. 1, in the present embodiment, a non-enzymatic glucose biosensor 100 includes a voltage source 102, a reference electrode 104, an opposite electrode 106, and a working electrode 108. In particular, the reference electrode 104, the opposite electrode 106, and the working electrode 108 are respectively electrically connected to the voltage source 102, and the voltage source 102 respectively provides the given voltage and current to the reference electrode 104, the opposite electrode 106, and the working electrode 108.

In the present embodiment, the reference electrode 104 has a reference potential, and based on the reference potential, the potential of the working electrode 108 can be accurately configured. The reference electrode 104 is, for instance, a calomel electrode or a Ag/AgCl electrode. The main function of the opposite electrode 106 is to maintain the electrical neutrality of the solution, and the reaction occurring in the opposite electrode 106 does not affect the working electrode 108. The opposite electrode 106 is, for instance, white gold wire. The opposite electrode 106 at least surrounds a portion of the working electrode 108 to increase the current density and uniformity between the opposite electrode 106 and the working electrode 108, so as to increase the sensitivity and accuracy of the non-enzymatic glucose biosensor 100, but the invention is not limited thereto. In other words, in other embodiments, the opposite electrode 106 and the working electrode 108 can also be arranged and have other relative positions. Moreover, although the non-enzymatic glucose biosensor 100 of the present embodiment is exemplified by including the three-electrode system of the reference electrode 104, the opposite electrode 106, and the working electrode 108, the invention is not limited thereto. In other embodiments, the reference electrode 104, the opposite electrode 106, and the working electrode 108 in the non-enzymatic glucose biosensor 100 can also be arranged in other ways, or at least one of the reference electrode 104 and the opposite electrode 106 can be omitted.

In the present embodiment, the working electrode 108 includes a substrate 110 and a nanometal catalyst 112, wherein the nanometal catalyst 112 is deposited on the substrate 110 and includes polygonal block nanostructures, and the nanometal catalyst 112 catalyzes the oxidation reaction of glucose. In the present embodiment, the material of the substrate of the invention includes a soft flexible material, such as polyethylene terephthalate (PET). In the present embodiment, the nanometal catalyst 112 is, for instance, deposited on a portion of the substrate 110, but the invention is not limited thereto. In other words, in other embodiments, the nanometal catalyst 112 of the invention can also be deposited on the entire substrate 110. Moreover, in the present embodiment, the nanometal catalyst 112 is deposited into a circular region on the substrate 110 as an example, but the invention is not limited thereto. In other words, in other embodiments, the nanometal catalyst 112 of the invention can also be deposited into a region having other suitable forms on the substrate 110.

In the present embodiment, the nanometal catalyst 112 can have polygonal block nanostructures, and the specific configuration thereof is as shown in (a), (b), and (c) of FIG. 2. In particular, the nanometal catalyst 112 shown in (a) and (c) of FIG. 2 has popcorn-shaped block nanostructures, and the nanometal catalyst 112 shown in (b) of FIG. 2 has, for instance, flower-shaped or cloud-shaped block nanostructures. In other embodiments, in addition to having the block nanostructures, the nanometal catalyst 112 can further have coniferous nanostructures at the same time, and the specific form thereof is as shown in FIG. 2(d).

In the present embodiment, the width of the polygonal block nanostructures of the nanometal catalyst 112 is, for instance, between 50 nm and 100 nm. In the present embodiment, the nanometal catalyst 112 can have a single crystal structure, and the crystal system thereof is face-centered cubic. The main crystal faces of the face-centered cubic crystal system are (111), (200), and (220), and the crystal spacing orientation of the nanometal catalyst can be observed via a transmission electron microscope. In the present embodiment, the material of the nanometal catalyst 112 includes platinum.

In the present embodiment, the manufacturing method of the nanometal catalyst 112 is, for instance, a micro-electroplating process. In the present embodiment, the manufacturing method of the nanometal catalyst 112 includes, for instance, the following steps. First, a conductive material is provided. In the present embodiment, the conductive material can be titanium, aluminum, or platinum.

Then, the conductive material is brought in contact with an electroplating solution. In the present embodiment, the electroplating solution is, for instance, sulfuric acid, chloroplatinic acid, or a combination thereof

Next, a micro-electroplating is performed. In the present embodiment, the micro-electroplating is performed under the condition of, for instance, a voltage of 0.6 V to −0.5 V. In the present embodiment, when the electroplating is performed, the pH value of the electroplating solution is between 1 and 2. In the invention, the pH value, various compound concentrations, current, and voltage . . . etc. of the electroplating solution are adjusted to a specific range to obtain a nanometal catalyst having a specific form.

In the present embodiment, the nanometal catalyst 112 is formed by a micro-electroplating process as an example, but the invention is not limited thereto. In other words, in other embodiments, the nanometal catalyst 112 can also be manufactured by other methods such as a vacuum sputtering process.

In the present embodiment, the manufacturing method of the non-enzymatic glucose biosensor includes, for instance, the following steps. First, a voltage source 102 is provided. Next, a working electrode 108 electrically connected to the voltage source 102 is provided, wherein the working electrode 108 includes a nanometal catalyst 112, and the nanometal catalyst 112 is manufactured by the manufacturing method of the nanometal catalyst.

In the present embodiment, the reference electrode 104, the opposite electrode 106, and the working electrode 108 are respectively in contact with the specimen. Specifically, a portion of the reference electrode 104, the opposite electrode 106, and the working electrode 108 are respectively in contact with the specimen, but the invention is not limited thereto. Without affecting the accuracy and reproducibility of the measurement, the reference electrode 104, the opposite electrode 106, and the working electrode 108 can respectively be in contact with the specimen through any suitable portion thereof and in any suitable area. In the present embodiment, the nanometal catalyst catalyzes the oxidation reaction of glucose, such that the glucose in the specimen is oxidized into gluconic acid to produce a reaction current. The glucose concentration in the specimen is obtained by measuring the size of the reaction current.

FIG. 3 shows the relationship of current density and glucose concentration of the non-enzymatic biosensor of an embodiment of the invention.

In the present embodiment, the nanometal catalyst material of the non-enzymatic biosensor is exemplified by platinum. Referring to FIG. 3, the current density and the glucose concentration of the non-enzymatic biosensor of the present embodiment are positively correlated, and the linear interval of the linear regression line is about 0.5 mM to about 4 mM, which is a wide range. In particular, the slope of the linear regression line is about 97 to about 113, indicating the non-enzymatic biosensor of the invention has good sensitivity.

In the present embodiment, since the nanometal catalyst 112 has nanostructures having a diverse morphology, the sensitivity and the linear induction interval of the non-enzymatic glucose biosensor 100 can be more flexibly adjusted. Moreover, since the nanometal catalyst 112 has a large reactive area, the non-enzymatic glucose biosensor 100 of the invention has excellent sensitivity. In other words, the non-enzymatic glucose biosensor 100 of the present embodiment does not use an enzyme to catalyze the oxidation reaction of glucose, but instead uses the nanometal catalyst 112 to catalyze the oxidation reaction of glucose, and therefore excellent linear interval is achieved.

Based on the above, in comparison to a known glucose biosensor detecting glucose concentration based on the principle of catalyzing the oxidation reaction of glucose by an enzyme, the non-enzymatic glucose biosensor of the invention detects glucose concentration based on the principle of catalyzing the oxidation reaction of glucose by a nanometal catalyst, and therefore excellent linear interval is achieved. Moreover, since the nanometal catalyst has the advantage of large reactive area, the non-enzymatic glucose biosensor also has excellent sensitivity. It should be mentioned that, since the nanometal catalyst of the invention can be manufactured via simple process steps and equipment, when applied in the manufacture of a non-enzymatic glucose biosensor, commercial mass production of the non-enzymatic glucose biosensor can be facilitated. Moreover, since a nanometal catalyst having the desired configuration can be obtained by adjusting parameters of the non-enzymatic glucose biosensor such as pH value, various compound concentrations, current, and voltage of the electroplating solution, the sensitivity and linear induction interval can be flexibly adjusted such that the application scope of the non-enzymatic glucose biosensor can be increased.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A non-enzymatic glucose biosensor, comprising:
a voltage source; and
a working electrode electrically connected to the voltage source, wherein the working electrode comprises:
a substrate; and
a nanometal catalyst deposited on the substrate and comprising polygonal block nanostructures, wherein the nanometal catalyst catalyzes an oxidation reaction of glucose.

2. The non-enzymatic glucose biosensor of claim 1, wherein a width of the polygonal block nanostructures is between 50 nm and 100 nm.

3. The non-enzymatic glucose biosensor of claim 1, wherein the nanometal catalyst has a face-centered cubic single crystal structure.

4. The non-enzymatic glucose biosensor of claim 1, wherein a material of the nanometal catalyst comprises platinum.

5. The non-enzymatic glucose biosensor of claim 1, wherein the nanometal catalyst further comprises coniferous nanostructures.

6. The non-enzymatic glucose biosensor of claim 1, wherein a material of the substrate comprises a soft flexible material.

7. The non-enzymatic glucose biosensor of claim 1, further comprising an opposite electrode and a reference electrode respectively electrically connected to the voltage source.

8. A manufacturing method of a nanometal catalyst, comprising:
providing a conductive material;
bringing the conductive material in contact with an electroplating solution, wherein the electroplating solution comprises sulfuric acid, chloroplatinic acid, or a combination thereof; and
performing micro-electroplating on the conductive material under a condition of a voltage of 0.6 V to −0.5 V.

9. The manufacturing method of the nanometal catalyst of claim 8, wherein a pH value of the electroplating solution is between 1 and 2.

10. A manufacturing method of a non-enzymatic glucose biosensor, comprising:
providing a voltage source; and
providing a working electrode electrically connected to the voltage source, wherein the working electrode comprises a nanometal catalyst, and the nanometal catalyst is manufactured by the manufacturing method of the nanometal catalyst of claim 8.
